(19) United States
(12) Patent Application Publication
(10) Pub. No.: US 2018/0090314 A1
(43) Pub. Date: Mar. 29, 2018

(54) Methods and Apparatus for Printing High-Viscosity Materials

(71) Applicant: Orbotech Ltd., Yavne (IL)

(72) Inventors: Zvi Kotler, Tel Aviv (IL); Jonathan Ankri, Modiin (IL)

(21) Appl. No.: 15/709,486

(22) Filed: Sep. 20, 2017

Related U.S. Application Data
(60) Provisional application No. 62/400,635, filed on Sep. 28, 2016.
(60) Provisional application No. 62/447,471, filed on Jan. 18, 2017.

(51) Int. Cl. H01L 21/02; H01L 21/683

(52) U.S. Cl. CPC H01L 21/02266; H01L 21/683

(57) ABSTRACT

A method for disposing material includes positioning a donor film including a donor material at a predefined distance from an acceptor substrate, the donor film facing toward the acceptor substrate. One or more pulses of laser radiation are directed to impinge on the donor film at a given location so as to induce formation of a protrusion made from the donor material. A distal tip of the protrusion touches the acceptor substrate and disposes thereon while the protrusion is still in contact with the donor film. A spot of the donor material is formed on the acceptor substrate by increasing a separation between the donor film and the acceptor substrate so as to detach the distal tip of the protrusion from the donor film.

### CROSS-REFERENCE TO RELATED APPLICATIONS

This application claims the benefit of U.S. Provisional Patent Application 62/400,635, filed Sep. 28, 2016, and of U.S. Provisional Patent Application 62/447,471, filed Jan. 18, 2017, whose disclosures are incorporated herein by reference.

### FIELD OF THE INVENTION

The present invention relates generally to laser-induced material printing, and particularly to methods and systems for printing of high-viscosity materials.

### BACKGROUND OF THE INVENTION

Laser-Induced Forward Transfer (LIFT) technology offers an attractive cost/performance ratio for manufacturing and repairing Printed Circuit Boards (PCBs), Integrated Circuits (IC) substrates, Flat Panel Displays (FPDs) and other electronic devices. In the LIFT process laser photons are used for ejecting a volume of material from a source film (known as a “donor”) toward an acceptor substrate (known as “acceptor” or “receiver”).

### SUMMARY OF THE INVENTION

An embodiment of the present invention that is described herein provides a method for disposing material, including positioning a donor film including a donor material at a predefined distance from an acceptor substrate, the donor film facing toward the acceptor substrate. One or more pulses of laser radiation are directed to impinge on the donor film at a given location so as to induce formation of a protrusion made from the donor material. A distal tip of the protrusion touches the acceptor substrate and disposes thereon while the protrusion is still in contact with the donor film. A spot of the donor material is formed on the acceptor substrate by increasing a separation between the donor film and the acceptor substrate so as to detach the distal tip of the protrusion from the donor film.

In some embodiments, positioning the donor film at the predefined distance is carried out after directing the pulses of the laser radiation, and increasing the separation is carried out after the distal tip of the protrusion touches the acceptor substrate. In other embodiments, the method includes controlling an amount of the disposed donor material by controlling the predefined distance between the donor film and the acceptor substrate. In yet other embodiments, directing the pulses of the laser radiation includes setting at least one parameter of the laser pulses based on the predefined distance.

In an embodiment, the method includes disposing additional donor material on top of the disposed donor material at the given location by (i) re-positioning the donor film at the predefined distance without applying additional pulses of the laser radiation and (ii) increasing the separation between the donor film and the acceptor substrate again. In another embodiment, the method includes disposing on the acceptor substrate a contiguous pattern of the donor material, by performing one or more of: spatially shaping a beam of the laser radiation, and directing one or more additional pulses of the laser radiation to impinge on the donor film at a predefined spacing from the given location. In yet another embodiment, directing the pulses of the laser radiation includes scanning the laser radiation to impinge on the donor film at multiple points.

In some embodiments, directing the pulses of the laser radiation includes splitting the laser radiation to multiple beams that impinge on the donor film at multiple respective locations separated from one another. In other embodiments, the method includes, before finally disposing the protrusions on the acceptor substrate, forming the protrusions by (i) positioning an auxiliary substrate at a given distance from the donor film, (ii) shaping the protrusions by increasing a separation between the donor film and the auxiliary substrate and (iii) removing the auxiliary substrate. In yet other embodiments, the auxiliary substrate includes an allocated area of the acceptor substrate.

In an embodiment, the auxiliary surface includes a substrate different from the acceptor substrate. In another embodiment, the donor material has an equivalent viscosity level higher than 10,000 centipoise at a temperature of 25° C. In yet another embodiment, directing the pulses of the laser radiation includes forming a geometrical pattern of spots on the acceptor substrate, by directing the pulses to multiple different locations on the donor film and inducing the formation of multiple protrusions at the multiple locations, and including, after forming the protrusions, printing the geometrical pattern by increasing a separation between the donor film and the acceptor substrate so as to detach distal tips of the protrusions from the donor film.

In some embodiments, the method includes repeating printing of the geometrical pattern without applying additional pulses of the laser radiation. In other embodiments, the donor material includes a given material whose viscosity decreases under shear stress. In yet other embodiments, the shear stress is caused by the one or more pulses of laser radiation impinging on the donor film.

In an embodiment, in response to removal of the shear stress, the viscosity level of the given material returns to its pre-stress level after a time delay between 100 microseconds and 100 milliseconds. In another embodiment, the given material includes a form selected from a list consisting of an ink, a paste, a gel, and dispersions comprising particles.

There is additionally provided, in accordance with an embodiment of the present invention, an apparatus for disposing material, the apparatus including a positioning assembly and an optical assembly. The positioning assembly is configured to position a donor film including a donor material at a predefined distance from an acceptor substrate, the donor film facing toward the acceptor substrate. The optical assembly is configured to generate one or more pulses of laser radiation and to direct the one or more pulses to impinge on the donor film at a given location so as to induce formation of a protrusion made from the donor material. A distal tip of the protrusion touches the acceptor substrate and disposes thereon while the protrusion is still in contact with the donor film. After forming the protrusion, the positioning assembly is configured to form a spot of the donor material on the acceptor substrate by increasing a separation between the donor film and the acceptor substrate so as to detach the distal tip of the protrusion from the donor film.

The present invention will be more fully understood from the following detailed description of the embodiments thereof, taken together with the drawings in which:

### BRIEF DESCRIPTION OF THE DRAWINGS

FIG. 1 is a schematic, pictorial illustration of a Laser-Induced Forward Transfer (LIFT) system for printing on a substrate, in accordance with an embodiment of the present invention;

FIG. 2 is a schematic, sectional view showing steps of a process for printing viscous materials using LIFT techniques, in accordance with an embodiment of the present invention;

FIG. 3 is a flow chart that schematically illustrates a method for printing viscous materials using LIFT techniques, in accordance with an embodiment of the present invention;

FIG. 4 is a schematic, sectional view showing steps of a process for assisting printing of viscous materials using a sacrificial substrate, in accordance with another embodiment of the present invention; and

FIG. 5 is a schematic, pictorial illustration of experimental results of printing a matrix of viscous materials using LIFT techniques, in accordance with an embodiment of the present invention.

### DETAILED DESCRIPTION OF EMBODIMENTS

### Overview

Embodiments of the present invention that are described hereinbelow provide improved methods and apparatus for depositing materials using Laser-Induced Forward Transfer (LIFT) techniques. Although the embodiments described herein refer mainly to materials having high viscosity, the disclosed techniques are applicable to a wide variety of materials and applications. In the description that follows, for the sake of clarity, the terms “printing”, “depositing” and “disposing” are used interchangeably.

High viscosity materials, which are often (although not necessarily) defined as materials having a viscosity level higher than 10,000 centipoise (CPS) at a temperature of 25° C., are used in various applications such as adhesives in the production of electronic devices. In principle, high-viscosity materials may be printed on a substrate using dispensing techniques or stencil printing. Such techniques, however, are typically limited to printing dots larger than 200 μm in diameter. Furthermore, such techniques are typically limited to a printing rate of about 300 dots per second or less, depending on the viscosity of the materials used.

In some electronic devices, such as mobile devices, small form factor and low weight are important requirements. In printing viscous materials, such as metal pastes, electrically conductive adhesives (ECA), Nonconductive adhesives (NCA) or solder pastes (SP), under such requirements, it is important that the target dot diameter be smaller than 200 μm, and preferably smaller than 100 μm.

In some embodiments, a donor film made from one or more types of viscous materials such as ECA, NCA or SP, is formed on a donor substrate. In an embodiment, the donor film is positioned at a predefined distance (e.g., 1 mm) from an acceptor substrate, such as a flat panel display (FPD), a printed circuit board (PCB), or an integrated circuit (IC) substrate so that the viscous material of the donor film is facing the acceptor substrate.

In some embodiments, a laser source, such as a diode laser, is configured to irradiate laser pulses of 915 nm wavelength at a power of 150 Watts and a pulse width of 1-10 microseconds. The laser pulses are directed to impinge on the donor film at one or more predefined locations. The high energy conveyed in the laser pulses causes the viscous material of the donor film at the impinging locations and in proximity to the donor substrate, to vaporize. The formed local, transient pressure drives the formation of a protrusion made from the viscous donor material, which extends out of the donor film towards the acceptor substrate.

In some embodiments, the donor film is moved towards the acceptor substrate until the distal tips of the protrusions touch the surface of the acceptor substrate, while still also connected to the donor film. The donor film is then moved away from the acceptor substrate so that the protrusions are torn from the donor film, thereby printing viscous material from the distal tips of the protrusions on the acceptor substrate. (By way of example, the description above refers to a moving donor and a stationary acceptor. Alternatively, the distance between the donor and acceptor can be changed by moving the acceptor and retaining the donor stationary, or by moving both.)

In some embodiments, the amount of donor material that will be printed on the acceptor substrate is determined by the difference between the maximal length of the induced protrusion (as obtained when the acceptor substrate is positioned at a sufficiently large distance from the donor film so that the protrusion cannot touch the acceptor substrate) and the minimal distance set between the donor film and the acceptor substrate. In these embodiments, as long as the distance between the donor film and an upper surface of the acceptor substrate exceeds the maximal length of the protrusion, no donor material will be printed on the acceptor substrate.

To print a spot smaller than 100 μm on the acceptor substrate, after forming the protrusion, the donor film may be positioned at a distance slightly smaller than the maximal length of the protrusion from the acceptor substrate, and then retracted so as to print the spot.

In some embodiments, a viscous material may be printed on the acceptor substrate to form printed dots having desired three-dimensional (3D) shapes. For example, a 3D structure such as a pillar may be printed on the acceptor substrate by repeating the printing sequence described above multiple times, without horizontally moving the donor film or the acceptor substrate. In this embodiment, each application of the sequence forms an additional layer of the viscous material on top of the already formed pillar, thus enabling the formation of tall and narrow pillars, also known as high aspect ratio (HAR) pillars.

In some embodiments, the disclosed techniques may be used to print lines or other elongated patterns of the viscous material, not only dots. Printing of patterns can be performed, for example, by shaping the laser beam to have the desired spatial pattern, and/or by printing a series of partially-overlapping dots of viscous material by moving the laser beam over the donor film.

In some embodiments, a sacrificial substrate may be used to shape the cross sections of the protrusions. For example, in some cases the actual cross sections of the protrusions as formed have different dimensions than planned. In such cases, the sacrificial substrate may be pressed against the distal tips of the protrusions and pulled away from the donor film in a controlled manner so as to shape the protrusions to the desired dimensions. Then, the shaped protrusions are applied to the actual acceptor substrate for printing.

The disclosed printing techniques can be used for producing various devices, such as hand held devices, mobile phones, internet-of-things (IoT) devices or other mobile devices, or any suitable devices having small form factor and low weight. Furthermore, by using the disclosed techniques, significant cost reduction in producing such devices is possible due to increased printing rate by a factor of ten.

### System Description

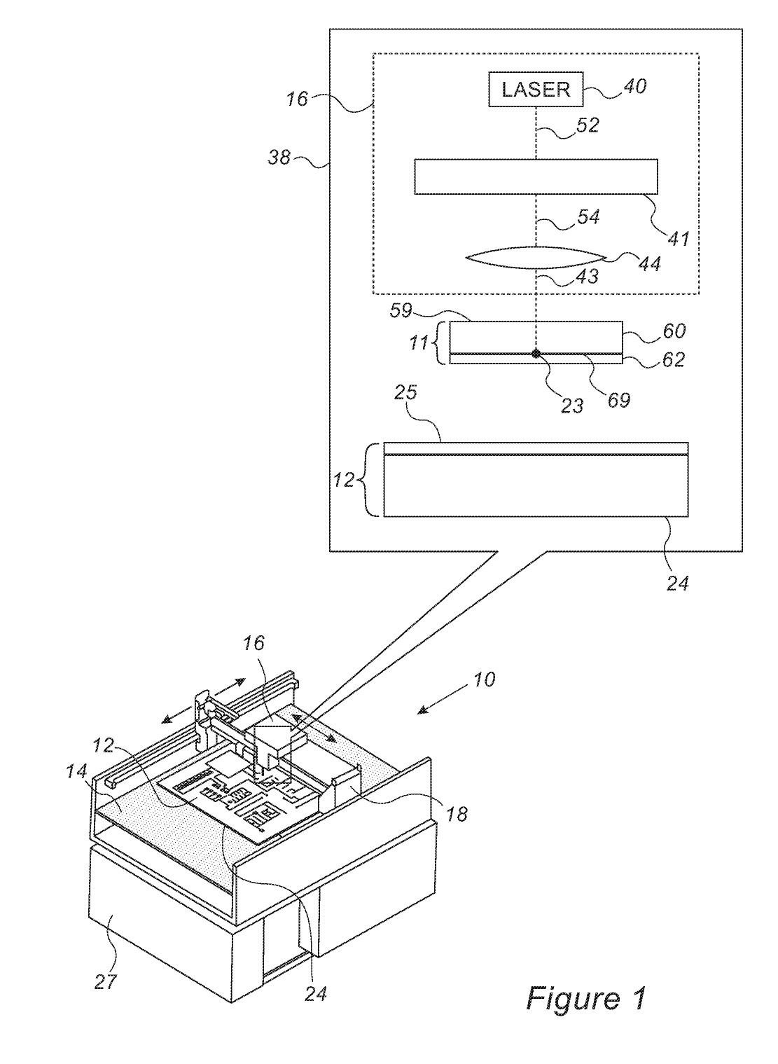

FIG. 1 is a schematic, pictorial illustration of a laser-induced forward transfer (LIFT) system 10, in accordance with an embodiment of the present invention.

In some embodiments, system 10 is configured to print various materials on a substrate 24 of an electronic circuit, referred to herein as acceptor board 12, such as a flat panel display (FPD), a printed circuit board (PCB) or an integrated circuit (IC) substrate, which is held on a mounting surface 14. In LIFT processes, board 12 is also referred to herein as a “receiver” or an “acceptor.” The terms “Flat panel Display,” “FPD,” “printed circuit board,” “PCB,” “integrated circuit substrate,” and “IC substrate” are used herein to refer generally to any suitable substrate on which materials are deposited.

In some embodiments, system 10 is configured to deposit materials having equivalent viscosity level higher than 10,000 centipoise (CPS) at a temperature of 25° C., such as adhesive materials, electrically conductive adhesives (ECA), Non-conductive adhesives (NCA), solder pastes (SP) or metal pastes (nanoparticle or micro-particle metal pastes) or dielectric pastes. Generally, however, the disclosed techniques are not limited to any particular material.

In an embodiment, system 10 comprises a positioning assembly 18, which is configured to position an optical assembly 16 over desired sites of substrate 24, by moving optical assembly 16 linearly along selected axes of system 10. In some embodiments, positioning assembly 18 may comprise a moving bridge configured to move along one or more axes, e.g., horizontal axes X, Y, and a vertical axis Z. In other embodiments, positioning assembly 18 may comprise a moving stage. Alternatively, other suitable techniques can be used to move positioning assembly 18 and board 12 relative to one another. A control unit 27 controls several functionalities of system 10, such as the operation of optical assembly 16 and positioning assembly 18.

Control unit 27 typically comprises a general-purpose computer, which is programmed in software to carry out the functions described herein. The software may be downloaded to the computer in electronic form, over a network, for example, or it may, alternatively or additionally, be provided and/or stored on non-transitory tangible media, such as magnetic, optical, or electronic memory.

Reference is now made to an inset 38, which is a schematic side view capturing optical assembly 16, a donor 11, and board 12.

In some embodiments, optical assembly 16 comprises a laser 40, such as a high power fiber coupled diode laser (HPFCDL) product K915FG2RN-150.0W made by BWT Beijing Ltd (2nd Fl, No. 4A Hangfeng Rd. Fengtai Beijing 100070, China), or a similar product made by nLight Corporation, Vancouver, Wash. 98665, or by any other supplier of such lasers.

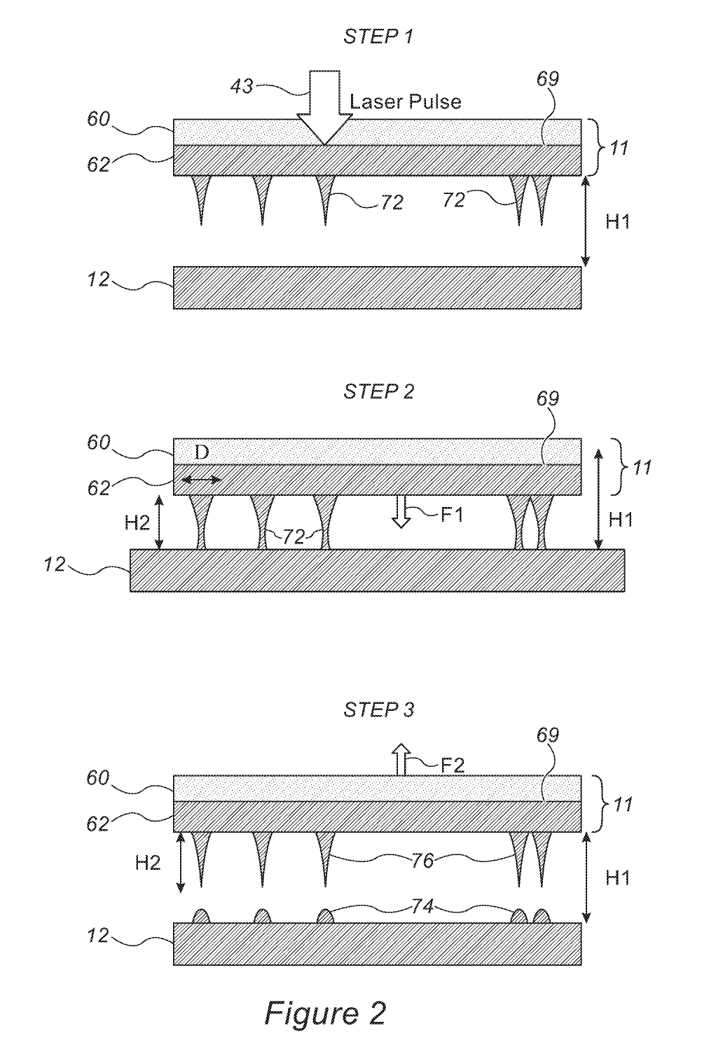

In an embodiment, laser 40 may emit a pulsed beam 52 at a 915 nm wavelength and power of 150 W, or any other suitable wavelength and power level. In some embodiments, the pulses generated by laser 40 may have a pulse width of 1-10 microseconds, so as to irradiate donor 11 at energy levels of 150 μJ to 1.5 mJ. Such an energy level enables the formation of protrusions of the donor material from a donor film 62 as will be depicted in detail in FIG. 2 below.

In an embodiment, a beam scanning assembly 41 manipulates beam 52 into one or more beams 54 that are focused through optics 44 so as to form one or more beams 43, e.g., by splitting beam 43 into multiple sub-beams. In an embodiment, donor 11 comprises a substrate 60, typically made from an optically transparent material, such as a glass or plastic sheet. Optics 44 focuses each beam 43 through a top surface 59 of substrate 60 to impinge a surface 69 of donor film 62 at a desired location, such as a location 23.

In some embodiments, beam 43 induces formation of the viscous material to be ejected as protrusions from film 62 onto board 12.

In some embodiments, beam scanning assembly 41 further comprises a scanner (not shown) having a suitable scanning mechanism, such as galvo mirrors, which scans beams 43 so as to induce the formation of the protrusions depicted in FIG. 2 at a frequency rate higher than 3 KHz or any other suitable rate.

In an embodiment, the scanner of beam scanning assembly 41 is configured to scan beam 43 on surface 69 so as to induce the formation of thousands of protrusions per second, thus, disposing the donor material on acceptor board 12 at a substantially similar printing rate.

In some embodiments, the scanner of beam scanning assembly 41 is configured to direct beams 43 to location 23 at a typical positioning accuracy of less than 5 μm. In an embodiment, a typical distance between donor 11 and board 12 is on the order of 1 mm or larger. At this distance, positioning assembly 18 is configured to position optical assembly 16 and donor 11 relative to board 12 at a typical positioning accuracy of less than 10 μm. Therefore, the total positioning accuracy of system 10 supports printing the material of film 62 on board 12 at a typical accuracy of 10 μm-20 μm. The printing accuracy may be further improved using any other suitable scanning and positioning assemblies.

In some embodiments, beam 43 may form a spherically symmetric spot at location 23, thereby inducing formation of a corresponding spherically symmetric protrusion.

In other embodiments, optical assembly 16 is configured to shape beam 43 to a contiguous cross section, such as a linear cross section, so as to induce formation of contiguous protrusions such as lines or curved line segments on board 12.

In another embodiment, optical assembly 16 is further configured to split beam 43 into multiple sub-beams and to direct multiple pulses of the multiple sub-beams of beam 43 to impinge on surface 69 at multiple locations with close proximity to one another so as to induce the formation of contiguous protrusions that enable printing on board 12 a contiguous pattern.

In yet another embodiment, after printing a first pattern at a given location (e.g., location 23) on board 12, positioning assembly 18 is further configured to reposition optical assembly 16 and donor 11 relative to board 12, so as to print an additional layer on the same pattern at location 23, or to print a second pattern in close proximity to the first pattern. Additional embodiments for printing are depicted in FIGS. 2-5 below.

In other embodiments, system 20 may comprise any other suitable type of laser 40, such as a continuous-wave (CW) modulated laser, a quasi-CW fiber laser, or a pulsed fiber laser having a range of pulse widths between a few nanoseconds and a few hundreds of nanoseconds (e.g., YAG-based or Ytterbium-based fiber laser). Such lasers are produced, for example, by IPG photonics or Spectra-Physics.

The disclosed configuration of system 10 and its components are depicted here by way of example, so as to illustrate the sort of environment in which the techniques described herein may be implemented. Such techniques may similarly be carried out using any other suitable equipment and configurations.

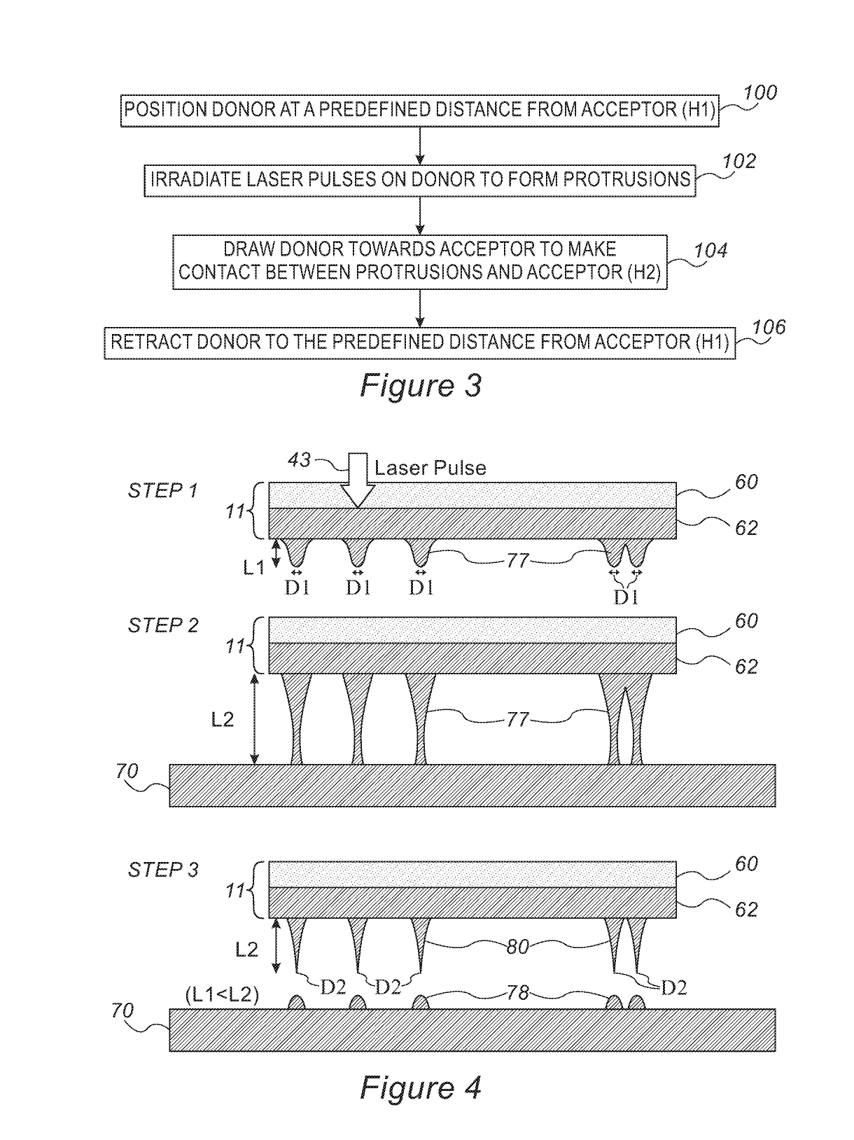

FIG. 2 is a schematic sectional view showing a multi-step process for printing viscous materials using system 10, in accordance with an embodiment of the present invention. The process depicted in FIG. 3 is broken into three steps purely for the sake of conceptual clarity.

Reference is now made to a step 1. In some embodiments, positioning assembly 18 positions film 62 of donor 11 at a distance denoted H1 (e.g., 2 mm or 3 mm) from acceptor board 12. In an embodiment, film 62 comprises one or more materials having equivalent viscosity level higher than 10,000 CPS at a temperature of 25° C., such as metallic pastes, adhesive materials, ECA, NCA, and SP, as described in FIG. 1 above. The materials comprising film 62 are pre-coated on substrate 60 using any suitable deposition techniques known in the art. In an embodiment, optical assembly 16 directs beam 43 to impinge on film 62 at one or more predefined locations, such as location 23 (in FIG. 1).

In some embodiments, the interaction between beam 43 and film 62 heats the viscous material of film 62 at the interface with substrate 60 at the impinging locations. In an embodiment, the excess heat causes the formation of one or more hot bubbles of gas (not shown) at the interface. The gas in the bubbles applies pressure on film 62 at the impinging locations, thereby forms protrusions 72 that extend out of film 62 toward acceptor board 12.

In some embodiments, film 62 comprises materials of non-Newtonian viscosity (e.g., fluid materials not obeying Newton's law of viscosity). The viscosity of such materials decreases (typically in a substantial amount) in the presence of a fast shear stress induced, for example, by the interaction between beam 43 and film 62. The phenomena of viscosity reduction in the presence of shear stress is also referred to herein as “shear thinning.” The viscosity of such materials typically returns to its initial value (i.e., before applying the shear stress) after removing the shear stress.

In the example of step 1, when beam 43 impinges on film 62, the shear thinning of film 62 at the impinging location induces the extension of protrusion 72 out of film 62 toward substrate 12. After beam 43 is removed from the impinging location, the viscosity of the material increases, thereby reducing the progress of the extension of protrusion 72 to a complete stop, which determines the dimensions (e.g., length) of protrusion 72 as shown in step 1.

In these embodiments, the length of protrusion 72 depends on the characteristics of beam 43 (e.g., power and pulse width of the beam) and on properties of the non-Newtonian viscous materials comprising film 62. For example, non-Newtonian viscous materials having high initial viscosity (e.g., viscosity level higher than 10,000 CPS) may exhibit minor shear thinning in the presence of a shear stress.

In some embodiments, the shear thinning property of some materials having non-Newtonian viscosity may be time-dependent (also referred to herein as “thixotropic”), such that after removing the shear stress, the viscosity returns to its initial value only after some time delay, rather than immediately. This time delay is referred to herein as “recovery time” of the viscosity.

In some embodiments, the recovery time of a selected non-Newtonian viscous material is required to be shorter than the total time it takes protrusion 72 to reach its specified length. In other words, the recovery time has to be shorter than the ratio L/v, wherein L is the specified length of protrusion 72, and v is an average progression velocity of protrusion 72. The inventors found that typical values of required recovery time of suitable non-Newtonian viscous materials, are on the order of 100 microseconds to 10's of milliseconds (e.g., 100 milliseconds,) so as to control the specified length and shape of protrusion 72 in the configuration described in FIG. 1 above.

In some embodiments, the properties of such non-Newtonian viscous materials can be controlled by using suitable additives, such as organic molecules and particles, or by controlling the acidity level (PH) of these materials, or by selecting polymers having predefined molecular weights. Furthermore, various dispersions comprising nanoparticles (silica or otherwise metals) show enhanced shear thinning and can be accompanied with fast recovery.

In some embodiments, the materials having non-Newtonian viscosity may appear in various suitable forms, such as but not limited to a form of, an ink, a paste, a gel, and dispersions comprising micro-particles and/or nano-particle at a volumetric content that exceeds 20% of the total volume of the material. These materials comprising film 62 are pre-coated on substrate 60 using any suitable deposition techniques known in the art.

Reference is now made to a step 2. In an embodiment, positioning assembly 18 moves donor 11 in a direction denoted F1 towards board 12, and positions donor 11 so that film 62 is at a distance H2 (e.g., 0.1 mm) from board 12, smaller than H1, so as to make a physical contact between the distal tips of protrusions 72 and the top surface of board 12. Note that at step 2, the proximal ends of protrusions 72 are still in contact with film 62, and the distal tips of protrusions 72 are touching acceptor board 12.

In some embodiments, the proximal end of each protrusion 72 is wider than its distal tip. The diameter of the proximal end of protrusion 72 at the surface of film is denoted D, (in case of a symmetrically round protrusion.) The diameter of the distal tip of protrusion 72 is typically substantially smaller than diameter D, typically on the order of a few tens of microns.

Reference is now made to a step 3. In some embodiments, positioning assembly 18 moves donor 11 in a direction denoted F2 away from board 12, so as to reposition film 62 at distance H1 from board 12 (or any other suitable distance). In an embodiment, an adhesion force between the distal tips of protrusions 72 and board 12 causes protrusions 72 to split into traces 74 disposed on board 12, and proximal ends 76 that remains attached to the surface of film 62.

In some embodiments, the amount of material printed on board 12, which may indicate the dimensions of traces 74 printed on board 12, may be controlled in various ways. In principle, the amount of material printed using the three-step process depicted in FIG. 2 may be determined by the ratio between the estimated maximal achievable length of protrusion 72 (without having board 12 as a stopper) and the distance between donor 11 and acceptor board 12.

In an embodiment, the total energy of beam 43 may be controlled by controlling the power of laser 40, and/or by controlling the pulse width of beam 52. Impinging a higher-energy beam 43 on film 62 effectively increases the maximal length of protrusion 72, resulting in a larger dimension of trace 74 (assuming the same distance H2). In another embodiment, a larger trace 74 may be obtained by setting a smaller distance H2 between donor 11 and acceptor board 12.

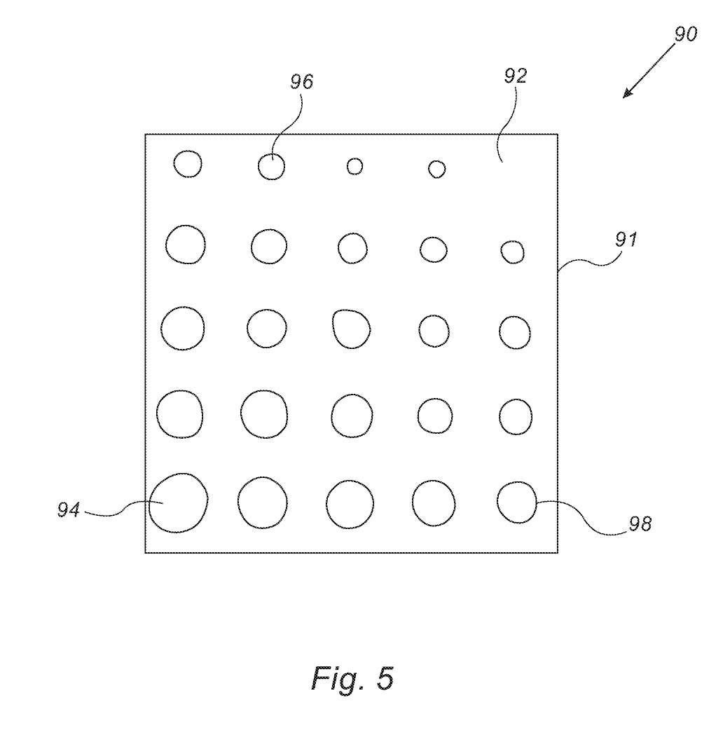

The embodiments related to controlling the dimensions of the printed traces, such as trace 74, are further described in FIG. 5 below.

In some embodiments, repeating the three-step process depicted in FIG. 2 enables printing multiple layers of trace 74, on top of one another. In this embodiment, in each repetition of this sequence an additional layer of trace 74 is printed on top of the trace previously printed at the same location on board 12. For example, five repetitions of the sequence may result in printing a three-dimensional (3D) pillar made from five traces 74 stacked vertically. Furthermore, since this embodiment does not require moving positioning assembly 18 laterally, the method supports fast printing of 3D patterns on board 12 at a printing rate of several thousands of traces per second.

Furthermore, since lateral movement of positioning assembly 18 is not required, the positioning accuracy of each trace 74 layer depends solely on the positioning accuracy of the scanner of beam scanning assembly 41, which typically has a positioning error lower than 5 μm. In other embodiments, after completing the printing of trace 74, protrusion 76 is still usable, and system 20 is configured to print the 3D pillar by repeating only steps 2 and 3, without reapplying beam 43 on film 62. In this embodiment, the positioning error of the scanner is eliminated, and therefore, the positioning accuracy of the stacked traces is further improved. This positioning accuracy enables printing tall and narrow pillars (i.e., high aspect ratio pillars, as defined below) made from multiple traces 74 stacked on top of one another. The ratio between the height and the diameter of the pillar is referred to herein as an “aspect ratio.” An aspect ratio that is considered as a high aspect ratio (HAR), is substantially larger than 1.

The improved positioning accuracy enables constructing HAR 3D features, by vertically stacking a large number of round traces of small diameter (or having any other suitable shape).

In alternative embodiments, donor 11 is static and at step 2, positioning assembly 18 moves board 12 up, i.e., towards donor 11 to make the contact between protrusions 76 and board 12, and thereafter, at step 3, positioning assembly 18 retracts board 12 away from donor 11 so as to print traces 74 on board 12.

FIG. 3 is a flow chart that schematically illustrates a method for printing viscous materials using LIFT techniques, in accordance with an embodiment of the present invention. The method begins with positioning assembly 18 positioning donor 11 so that film 62 is at a predefined distance H1 from acceptor board 12, at a donor positioning step 100.

At a protrusions formation step 102, laser 40 irradiates beam 43 that impinges on film 62 at desired locations, such as location 23, so as to form protrusions 72. In an embodiment, beam scanning assembly 41 is configured to scan beam 43 over surface 69 at thousands of locations so that beam 43 impinges on surface 69 at the corresponding locations (such as location 23) separated from one another, so as to form thousands of protrusions 72 without requiring to move donor 11 along horizontal axes X, Y. At a donor drawing step 104, positioning assembly 18 draws donor 11, so as to set distance H2 between film 62 of donor 11 and board 12, and to make physical contact between protrusions 72 and board 12. At a retraction step 106 that concludes the method, positioning assembly 18 retracts donor 11 away from board 12, so as to print traces 74 on board 12.

In some embodiments, the method may loop back to donor drawing step 104 so as to begin a subsequent printing cycle in which another layer of traces is printed on top of traces 74 without applying additional pulses of beams 43 on surface 69.

In other embodiments, the method may loop back to protrusions formation step 102 so as to begin a subsequent printing cycle in which another layer of traces is printed on top of traces 74 by scanning beam 43 to apply pulses at location 23 on the donor. In an embodiment, repeating the method depicted in FIG. 3 multiple times (with or without reapplying beam 43) enables the formation of HAR 3D pillars, as described in FIG. 2 above.

FIG. 4 is a schematic, sectional view showing a three-step process for assisting printing of viscous materials using a sacrificial substrate 70, in accordance with embodiments of the present invention. FIG. 4 depicts a sequence of three process steps purely for the sake of conceptual clarity. In practice, the sequence may comprise more than three steps as well as sub-steps, or fewer step.

Reference is now made to a step 1. In some embodiments, beam 43 impinges on film 62 and induces formation of protrusions 77. In the example of step 1, protrusions 77 have a typical length denoted L1, and their distal tips have a typical diameter denoted D1. L1 is shorter than a desired length L2 (shown in step 2), and D1 is wider than a desired diameter D2 of the distal tips (shown in step 3). In an embodiment, the diameter (or width) of the distal tips of protrusions 77 typically determines the printed diameter of the dots, such as traces 74.

In the present example, L1 is smaller than 0.1 mm and D1 is wider than 50 μm, which are the required values for carrying out the desired printing process of the viscous material of film 62.

The unsuitable length L1 and/or diameter D1 may be due, for example, to insufficient energy of beam 43, to an exceedingly high viscosity of the material comprising film 62, the rheological behavior of the material of film 62 under fast shearing rate under the impact of beam 43, or to any other reason.

Reference is now made to step 2. In some embodiments, positioning assembly 18 positions an auxiliary substrate (referred to herein as a sacrificial substrate) such as a blank substrate 70, below donor 11. In an embodiment, positioning assembly 18 moves donor 11 towards substrate 70 so that the distal tips of protrusions 77 make contact with the upper surface of substrate 70. Then, positioning assembly 18 retracts substrate 70 away from donor 11 in a controlled manner, so that an adhesion force between the distal tips of protrusions 77 and substrate 70 enables shaping the length and width of protrusions 77.

Reference is now made to a step 3. In some embodiments, the retraction of substrate 70 and the adhesion force between the distal tips of protrusions 77 and substrate 70 cause protrusions 77 to split into traces 78 disposed on substrate 70, and to shape proximal ends 80 to length L2 and diameter D2, which are the desired shape to resume the printing process.

In an embodiment, after shaping proximal ends 80, substrate 70 is removed from system 10 by positioning assembly 18 (or alternatively by an operator) and replaced by acceptor board 12 of FIG. 2 above. In an embodiment, positioning assembly 18 moves donor 11 towards board 12 to a distance smaller than L2 so that the top surface of board 12 makes contact with the distal tips of proximal ends 80, and then retracts donor 11 away from board 12 in a controllable manner so as to print a trace, such as trace 74 of FIG. 2 above. (These intermediate steps are not shown in FIG. 4, but a substantially similar operation was already described above in steps 2 and 3 of FIG. 2.) Note that, as depicted in steps 2 and 3, shaping the length of the protrusions from L1 to L2 and the diameter of their distal tips, from D1 to D2 enables printing on acceptor board 12 dots, such as traces 74, at a desired diameter smaller than 50 μm.

In an alternative embodiment, steps 2 and 3 may be carried out on a designated location on board 12, instead of using a dedicated sacrificial substrate 70. In other words, a certain area on acceptor board 12 can be allocated to serve as a sacrificial area. This embodiment eliminates the need to use substrate 70.

In some embodiments, after step 3 donor 11 and an array of protrusions 80 may be used as a template pattern for printing. In an embodiment, one or more HAR 3D pillars may be produced, for example, by repeating the printing process on board 12 as described above, multiple times at a predefined location. In another embodiment, the template pattern may be printed at multiple locations (other than the predefined location) by carrying out the printing process on board 12 at each of these multiple locations. In this embodiment, positioning assembly 18 moves donor 11 along horizontal axes X, Y to one of the multiple locations. After positioning donor 11 at the desired location, positioning assembly 18 moves donor 11 (e.g., along the Z axis) towards board 12 to make contact with protrusions 80, followed by retracting donor 11 away from board 12 as described above. By repeating this move (along X, Y axes) and print sequence at least once at each of the multiple locations, system 10 may print the template pattern of step 3 at these multiple locations.

FIG. 5 is a schematic, pictorial illustration of experimental results of printing a matrix 90 of viscous materials using LIFT techniques, in accordance with an embodiment of the present invention. In some embodiments, matrix 90 comprises a substrate 91 that is positioned in system 10 having its top surface facing a donor film, such as donor film 62 shown in FIGS. 2 and 4 above. In the present example experiment, system 10 was configured to induce a series of protrusions (not shown) for printing a matrix of dots on substrate 91. The donor film and the acceptor substrate were not parallel to one another, i.e., the distance between them is not constant, hence the different dot sizes. The terms “trace” and “dot” are used herein interchangeably.

The dots printed on substrate 91 had a minimal size substantially smaller than 100 μm and a maximal size larger than 100 μm. In the example of matrix 90, the distance between the donor and the acceptor substrate (denoted herein as “H”) increases as we go from the lower left corner to the upper right corner on matrix 90. For example, the minimal distance at the lower left corner is 0.1 mm, and the maximal distance at the upper right corner (marked 92) is about 0.2 mm. Three example dots are denoted 94, 96 and 98 in the figure, having diameters of 115 μm, 55 μm, and 82 μm, respectively.

The experimental results of FIG. 5 demonstrate how the printed dot size can be controlled by setting the distance between facing surfaces of the donor and acceptor substrates. As noted above, similar results could be obtained with the donor film parallel to the acceptor substrate, and the length of the protrusions (denoted herein as “L”) set by tuning the energy of beam 43. In some embodiments, the ratio between H and L determines the size (e.g., diameter) of the printed dot/trace. When the value of H is smaller than the value of L, the larger the ratio L/H the larger the size of the printed dot. When the value of H is larger than the value of L, no dot is printed.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method for disposing material, comprising:
positioning a donor film comprising a donor material at a predefined distance from an acceptor substrate, wherein the donor film is facing toward the acceptor substrate;
directing one or more pulses of laser radiation to impinge on the donor film at a given location so as to induce formation of a protrusion made from the donor material, wherein a distal tip of the protrusion touches the acceptor substrate and disposes thereon while the protrusion is still in contact with the donor film; and
forming a spot of the donor material on the acceptor substrate by increasing a separation between the donor film and the acceptor substrate so as to detach the distal tip of the protrusion from the donor film.

2. The method according to claim 1, wherein positioning the donor film at the predefined distance is carried out after directing the pulses of the laser radiation, and wherein increasing the separation is carried out after the distal tip of the protrusion touches the acceptor substrate.

3. The method according to claim 1, and comprising controlling an amount of the disposed donor material by controlling the predefined distance between the donor film and the acceptor substrate.

4. The method according to claim 1, wherein directing the pulses of the laser radiation comprises setting at least one parameter of the laser pulses based on the predefined distance.

5. The method according to claim 1, and comprising disposing additional donor material on top of the disposed donor material at the given location by (i) re-positioning the donor film at the predefined distance without applying additional pulses of the laser radiation and (ii) increasing the separation between the donor film and the acceptor substrate again.

6. The method according to claim 1, and comprising disposing on the acceptor substrate a contiguous pattern of the donor material, by performing one or more of:
spatially shaping a beam of the laser radiation; and
directing one or more additional pulses of the laser radiation to impinge on the donor film at a predefined spacing from the given location.

7. The method according to claim 1, wherein directing the pulses of the laser radiation comprises scanning the laser radiation to impinge on the donor film at multiple points.

8. The method according to claim 1, wherein directing the pulses of the laser radiation comprises splitting the laser radiation to multiple beams that impinge on the donor film at multiple respective locations separated from one another.

9. The method according to claim 1, and comprising, before finally disposing the protrusions on the acceptor substrate, forming the protrusions by (i) positioning an auxiliary substrate at a given distance from the donor film, (ii) shaping the protrusions by increasing a separation between the donor film and the auxiliary substrate and (iii) removing the auxiliary substrate.

10. The method according to claim 9, wherein the auxiliary substrate comprises an allocated area of the acceptor substrate.

11. The method according to claim 9, wherein the auxiliary substrate comprises a substrate different from the acceptor substrate.

12. The method according to claim 1, wherein the donor material has an equivalent viscosity level higher than 10,000 centipoise at a temperature of 25° C.

13. The method according to claim 1, wherein directing the pulses of the laser radiation comprises forming a geometrical pattern of spots on the acceptor substrate, by directing the pulses to multiple different locations on the donor film and inducing the formation of multiple protrusions at the multiple locations, and comprising, after forming the protrusions, printing the geometrical pattern by increasing a separation between the donor film and the acceptor substrate so as to detach distal tips of the protrusions from the donor film.

14. The method according to claim 13, and comprising repeating printing of the geometrical pattern without applying additional pulses of the laser radiation.

15. The method according to claim 1, wherein the donor material comprises a given material whose viscosity decreases under shear stress.

16. The method according to claim 15, wherein the shear stress is caused by the one or more pulses of laser radiation impinging on the donor film.

17. The method according to claim 16, wherein in response to removal of the shear stress, the viscosity level of the given material returns to its pre-stress level after a time delay between 100 microseconds and 100 milliseconds.

18. The method according to claim 15, wherein the given material comprises a form selected from a list consisting of an ink, a paste, a gel, and dispersions comprising particles.

19. An apparatus for disposing material, the apparatus comprising:
a positioning assembly, which is configured to position a donor film comprising a donor material at a predefined distance from an acceptor substrate, wherein the donor film is facing toward the acceptor substrate; and
an optical assembly, which is configured to generate one or more pulses of laser radiation and to direct the one or more pulses to impinge on the donor film at a given location so as to induce formation of a protrusion made from the donor material, wherein a distal tip of the protrusion touches the acceptor substrate and disposes thereon while the protrusion is still in contact with the donor film,
wherein, after forming the protrusion, the positioning assembly is configured to form a spot of the donor material on the acceptor substrate by increasing a separation between the donor film and the acceptor substrate so as to detach the distal tip of the protrusion from the donor film.

20. The apparatus according to claim 19, wherein the positioning assembly is configured to position the donor film at the predefined distance after directing the pulses of the laser radiation, and to increase the separation after the distal tip of the protrusion touches the acceptor substrate.

21. The apparatus according to claim 19, wherein the positioning assembly is configured to control an amount of the disposed donor material by controlling the predefined distance between the donor film and the acceptor substrate.

22. The apparatus according to claim 19, wherein the optical assembly is configured to set at least one parameter of the laser pulses based on the predefined distance.

23. The apparatus according to claim 19, wherein the positioning assembly is configured to dispose additional donor material on top of the disposed donor material at the given location by (i) re-positioning of the donor film and (ii) increasing the separation between the donor film and the acceptor substrate again.

24. The apparatus according to claim 19, wherein the optical assembly is configured to dispose on the acceptor substrate a contiguous pattern of the donor material, by performing one or more of:
spatially shaping a beam of the laser radiation; and
directing one or more additional pulses of the laser radiation to impinge on the donor film at a predefined spacing from the given location.

25. The apparatus according to claim 19, wherein the optical assembly is configured to scan the laser radiation to impinge on the donor film at multiple points.

26. The apparatus according to claim 19, wherein the optical assembly is configured to split the laser radiation to multiple beams that impinge on the donor film at multiple respective locations separated from one another.

27. The apparatus according to claim 19, wherein, before finally disposing the protrusions on the acceptor substrate, the protrusions are formed using a sequence comprising: (i) the positioning assembly is configured to position an auxiliary substrate at a given distance from the donor film, (ii) the positioning assembly is configured to shape the protrusions by increasing a separation between the donor film and the auxiliary substrate, and (iii) the positioning assembly is configured to remove the auxiliary substrate.

28. The apparatus according to claim 27, wherein the auxiliary substrate comprises an allocated area of the acceptor surface.

29. The apparatus according to claim 27, wherein the auxiliary substrate comprises a substrate different from the acceptor substrate.

30. The apparatus according to claim 19, wherein the donor material has an equivalent viscosity level higher than 10,000 centipoise at a temperature of 25° C.

31. The apparatus according to claim 19, wherein the optical assembly is configured to form a geometrical pattern of spots on the acceptor substrate, by directing the pulses to multiple different locations on the donor film and inducing the formation of multiple protrusions at the multiple locations, and wherein the positioning assembly is configured to print the geometrical pattern by, after forming the protrusions, increasing a separation between the donor film and the acceptor substrate so as to detach distal tips of the protrusions from the donor film.

32. The apparatus according to claim 31, wherein the positioning assembly is configured to repeat printing of the geometrical pattern without additional pulses of the laser radiation being applied.

33. The apparatus according to claim 19, wherein the donor material comprises a given material whose viscosity decreases under shear stress.

34. The apparatus according to claim 33, wherein the shear stress is caused by the one or more pulses of laser radiation impinging on the donor film.

35. The apparatus according to claim 34, wherein in response to removal of the shear stress, the viscosity level of the given material returns to its pre-stress level after a time delay between 100 microseconds and 100 milliseconds.

36. The apparatus according to claim 33, wherein the given material comprises a form selected from a list consisting of an ink, a paste, a gel, and dispersions comprising particles.
